(19) United States
(12) Patent Application Publication
(10) Pub. No.: US 2006/0133172 A1
(43) Pub. Date: Jun. 22, 2006

(54) Apparatus and method for writing to and/or reading from a memory cell in a semiconductor memory

(76) Inventors: Florian Schnabel, Hohenkirchen (DE); Jens Polney, Munchen (DE)

Correspondence Address: PATTERSON & SHERIDAN, LLP;Gero McClellan / Infineon Technologies, 3040 POST OAK BLVD.,, SUITE 1500, HOUSTON, TX, 77056, US

(21) Appl. No.: 11/283,493

(22) Filed: Nov. 18, 2005

(30) Foreign Application Priority Data
Nov. 18, 2004 (DE) 10 2004 055 674.1

(51) Int. Cl. G11C 7/04

(52) U.S. Cl. 365/211

(57) ABSTRACT

The invention proposes an apparatus for writing to and/or reading from a memory cell in a semiconductor memory having a selection transistor and a storage capacitor, where the apparatus has a device which is used to influence a threshold voltage for the selection transistor contrary to the influence of an ambient temperature. The invention also proposes a method for writing to and/or reading from a memory cell in a semiconductor memory having a selection transistor and a storage capacitor, where the method comprises the following method steps: a) an ambient temperature for the memory cell is ascertained, and b) an electrical voltage is applied to a substrate well in the selection transistor as a function of the ascertained ambient temperature such that a threshold voltage for the selection transistor is influenced contrary to the influence of an ambient temperature.

### CROSS-REFERENCE TO RELATED APPLICATIONS

This application claims foreign priority benefits under 35 U.S.C. § 119 to co-pending German patent application number DE 10 2004 055 674.1, filed 18 Nov. 2004. This related patent application is herein incorporated by reference in its entirety.

### BACKGROUND OF THE INVENTION

1. Field of the Invention

The invention relates to an apparatus and a method for writing to and/or reading from a memory cell in a semiconductor memory.

2. Description of the Related Art

Dynamic memory cells in semiconductor memories, such as DRAMs, store information by storing charge in a storage capacitor which is selected and connected by a selection transistor via a word line. In this case, a flow of charge when writing the information travels from a driver transistor, which is also used as a sense amplifier, via a connecting line (bit line) and the selection transistor to the storage capacitor.

A critical characteristic in a specification for the semiconductor memory includes a time period t_{WR} which defines a time period between a write operation (WRITE) and deactivation of the word line. An extent for the time period t_{WR} is stipulated in the memory cell by virtue of, inter alia, a particular minimum of electrical charge needing to be written to the storage capacitor before the word line which actuates the selection transistor is deactivated. Deactivating the word line terminates the write operation. The minimum of electrical charge is prescribed by, inter alia, a sensitivity of the sense amplifier during the read operation (READ). What is also crucial for a time used to write a particular quantity of charge to the storage capacitor is an RC constant for the signal path described above.

### SUMMARY OF THE INVENTION

It is the object of the present invention to provide an apparatus for improved writing to a memory cell in a semiconductor memory.

The inventive apparatus is provided for writing to and/or reading from a memory cell in a semiconductor memory having a selection transistor and a storage capacitor, where the apparatus has a device which is used to influence a threshold voltage Vₜ for the selection transistor contrary to the influence of an ambient temperature.

This advantageously means that the inventive device is used to compensate for a temperature response in the threshold voltage Vₜ, which means that a time constant for a signal path which is used to write electrical charge into the storage capacitor of the memory cell is essentially independent of the temperature. This means that, by way of example, a specification parameter t_{WR} for the dynamic semiconductor memory is advantageously minimized for high and low temperatures and needs to be observed to an equally uncritical degree.

In one preferred development of the inventive apparatus, the device comprises an electrical voltage generator, with an electrical voltage generated by the voltage generator being applied to a substrate well in the selection transistor. The electrical voltage generated by the voltage generator represents an offset voltage which influences the threshold voltage Vₜ contrary to the influence of an ambient temperature via the substrate well in the selection transistor, advantageously in a direct mechanism of action.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 shows a schematic illustration of a dynamic memory cell having the inventive apparatus, and

FIG. 2 shows basic curves for the threshold voltage Vₜ over the ambient temperature.

### DETAILED DESCRIPTION OF THE PREFERRED EMBODIMENT

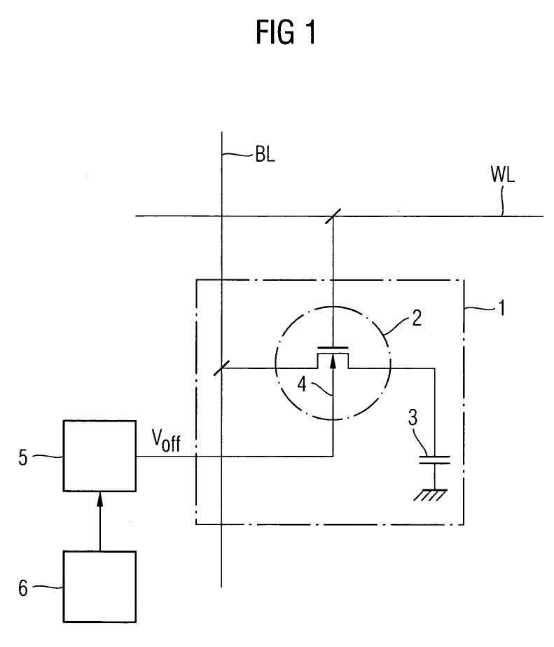

FIG. 1 schematically shows a dynamic memory cell 1 having a selection transistor 2 and a storage capacitor 3. During a write operation to the dynamic memory cell 1, a word line WL is used to turn on the selection transistor 2, and electrical charge is written from a bit line BL via the selection transistor 2 to the storage capacitor 3.

In this case, a significant influencing variable is a turned-on resistance Ron of the selection transistor 2 in the on state. This resistance is determined by the threshold voltage Vₜ, the threshold voltage Vₜ being proportional to the turned-on resistance Rₒₙ. A higher threshold voltage Vₜ signifies a higher turned-on resistance Rₒₙ, and vice versa. The threshold voltage Vₜ, like the turned-on resistance Rₒₙ, rises as temperature falls. This increases the RC constant of the signal path described above, which means that a specified time t_{WR}, indicating the time in which sufficient electrical charge needs to be written to the storage capacitor 3, needs to be observed more critically at low temperatures than at high temperatures.

The problems outlined are intensified even more by the fact that today's usual small feature sizes of semiconductor memories mean that a contact resistance between the selection transistor 2 and the storage capacitor 3 may be very high. This contact resistance is likewise part of the signal path for writing to/reading from the dynamic memory cell 1, which means that the entire RC constant of the signal path may conventionally be very high, which is a drawback. A time requirement for a write or read operation in the dynamic memory cell 1 may therefore be disadvantageously very high at low temperatures.

To compensate for any temperature dependency of the turned-on resistance Rₒₙ of the selection transistor 2, the invention proposes influencing the threshold voltage Vₜ of the selection transistor 2. This is achieved by virtue of an output of an electrical voltage generator 5 being connected to a substrate well 4 in the selection transistor 2, with the output outputting an offset voltage V_{off} to the substrate well 4. A temperature sensor 6 is used to ascertain an ambient temperature T for the dynamic memory cell 1, and to regulate the electrical voltage generator 5 on the basis of the ascertained ambient temperature. By way of example, the temperature sensor 6 may be arranged within a memory device (not shown) having a large number of dynamic memory cells 1. In this way, the threshold voltage Vₜ is influenced by the voltage generator 5 contrary to the influence of the ambient temperature. This makes it possible to compensate for a temperature response in the threshold voltage Vₜ of the selection transistor 2.

The fact that the threshold voltage Vₜ is proportional to the turned-on resistance Rₒₙ of the selection transistor 2 means that this also compensates for any temperature dependency of the turned-on resistance Rₒₙ of the selection transistor 2. This makes a write operation to the dynamic memory cell 1 uniform for low and for high temperatures to the extent that an RC constant for a signal path via which the charge is written to the storage capacitor 3 is essentially independent of temperature.

The temperature independency of the signal path means that besides the write operation it is also possible to perform a read operation from the storage capacitor 3 in the dynamic memory cell 1 in improved fashion. This can be substantiated in that a time specification parameter for the selection transistor 2 is easier to observe for the read operation for the essentially temperature-independent and hence constant turned-on resistance Rₒₙ of the selection transistor 2.

The inventive device having the voltage generator 5 and the temperature sensor 6 can thus advantageously be used to utilize or dimension time specification parameters for the dynamic memory cell 1 in the semiconductor memory in improved fashion. Advantageously, the read/write response of the dynamic memory cell 1 is therefore essentially independent of the ambient temperature. Memory devices having a large number of semiconductor memories with the inventive memory cells 1 thus allow accelerated timing properties and can therefore be of improved design.

Using suitable semiconductor implantations and dopings in the substrate well 4 in the selection transistor 2, it is possible to shape the threshold voltage Vₜ in a production process for the selection transistor 2. This is done through suitable selection of implantation sequences or implantation angles and depths in the substrate well 4. In addition, the threshold voltage Vₜ can be influenced through additional doping of a region between the source and drain (“channel implantation”) of the selection transistor 2. The channel implantation enhances or compensates for the doping of the substrate.

The methods outlined can be used to lower or raise an absolute value of the threshold voltage Vₜ and hence of the turned-on resistance Rₒₙ of the selection transistor 2 in advantageous fashion. Using the semiconductor implantations, it is thus possible to set the absolute value of the threshold voltage Vₜ to be as low as necessary and possible, so that the selection transistor 2 has well-defined switching properties both at low and at high ambient temperatures T.

Owing to the semiconductor implantations, the inventive compensation for the temperature response in the threshold voltage Vₜ results in a reduced threshold voltage Vₜ and hence in a further improvement in the read/write timing in the selection transistor 2 in the dynamic memory cell 1.

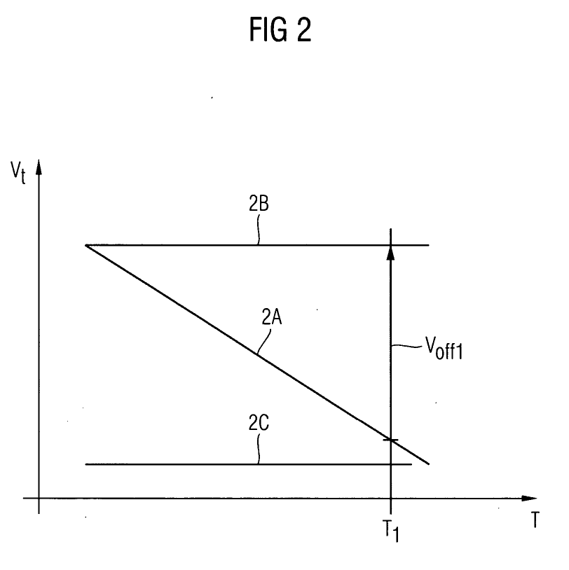

FIG. 2 uses three curves for the threshold voltage Vₜ over the ambient temperature T to show the basic mode of action of the inventive apparatus on a qualitative basis.

A curve 2A shows, in principle, a conventional curve for the threshold voltage Vₜ as a function of the ambient temperature T. It can be seen that the threshold voltage Vₜ falls as ambient temperature T rises, which means that the turned-on resistance Rₒₙ of the selection transistor 2 is high at low ambient temperatures and the result of this is a disadvantageously high RC constant for the read/write signal path of the dynamic memory cell 1. The inventive device having the electrical voltage generator 5 and the temperature sensor 6 is used to achieve a curve 2B for the threshold voltage Vₜ.

FIG. 2 shows, for example at an ambient temperature T₁, that the electrical voltage generator 5 applies a negative offset voltage V_{off1} to the substrate well 4 in the selection transistor 2. It can be seen that the absolute value of the applied offset voltage V_{off} becomes higher as ambient temperature T rises. Advantageously, this results in the threshold voltage Vₜ having a curve 2B which is essentially independent of the ambient temperature T. A curve 2C for the threshold voltage Vₜ shows a temperature-compensated threshold voltage Vₜ, which therefore results in the inventive temperature compensation being performed for a selection transistor 2 whose semiconductor implantation or doping is optimized with respect to the threshold voltage Vₜ. It can be seen that the inventive temperature compensation for the threshold voltage Vₜ results in the threshold voltage Vₜ having an absolute value which is smaller than the absolute value of the threshold voltage Vₜ in the curve 2B. This reduces the RC constant of the signal path for writing to/reading from the selection transistor 2 further, which further improves a read/write response in the selection transistor 2.

Although the invention has been described by way of example with reference to an n-FET, it goes without saying that the invention can also be applied to p-FETs. In this case, the inventive influencing of the threshold voltage Vₜ requires appropriate selection of a polarity for the offset voltage V_{off} of the electrical voltage generator 5. It is also regarded as advantageous that the invention can also be implemented with static memory cells.

The inventive apparatus may advantageously thus be used to speed up read and write operations for dynamic memory cells in semiconductor memories, or to make them more uniform, by a virtue of a resistance component in the form of the turned-on resistance Rₒₙ of the signal path for writing to/reading from the selection transistor 2 being at a minimum.

The aspects of the invention which are disclosed in the description, claims and drawings can be fundamental to the invention both individually and in combination.

While the foregoing is directed to embodiments of the present invention, other and further embodiments of the invention may be devised without departing from the basic scope thereof, and the scope thereof is determined by the claims that follow.

What is claimed is:

1. An apparatus for writing to and/or reading from a memory device, comprising:
a memory cell having a selection transistor and a storage capacitor; and
a temperature compensation device configured to influence a threshold voltage of the selection transistor in a manner responsive to an ambient temperature of the memory cell.

2. The apparatus of claim 1, wherein the temperature compensation device comprises an electrical voltage generator coupled to the selection transistor.

3. The apparatus of claim 1, wherein the temperature compensation device comprises an electrical voltage generator configured to apply an electrical voltage to a substrate well of the selection transistor.

4. The apparatus of claim 1, wherein the temperature compensation device comprises an electrical voltage generator configured to apply an electrical voltage to a channel region of the selection transistor.

5. The apparatus of claim 1, wherein the channel region is sufficiently doped to produce a desired characteristic response of the threshold voltage over a temperature range.

6. The apparatus of claim 1, further comprising a temperature sensor configured to determine the ambient temperature, and wherein the temperature sensor provides an output to the temperature compensation device.

7. The apparatus of claim 1, further comprising a temperature sensor configured to determine the ambient temperature, and wherein the temperature sensor provides an output to the temperature compensation device in order to regulate the temperature compensation device on the basis of the determined ambient temperature.

8. A memory device, comprising:
a memory cell having a selection transistor and a storage capacitor;
a temperature sensor configured to determine the ambient temperature, and wherein the temperature sensor provides an output signal reflective of the determined ambient temperature; and
a temperature compensation device having an input to receive the output signal and, responsively, apply an offset voltage to the selection transistor to influence a threshold voltage of the selection transistor; whereby the threshold voltage is controlled according to changes in the ambient temperature of the memory cell.

9. The memory device of claim 8, wherein the temperature compensation device comprises an electrical voltage generator configured to apply the offset voltage to a substrate well of the selection transistor.

10. The memory device of claim 8, wherein the temperature compensation device comprises an electrical voltage generator configured to apply the offset voltage to a channel region of the selection transistor.

11. The memory device of claim 10, wherein the channel region is sufficiently doped to produce a desired characteristic response of the threshold voltage over a temperature range.

12. A memory device, comprising:
a memory cell having a selection transistor and a storage capacitor; the memory cell having a temperature-sensitive threshold voltage; and
a temperature compensation device configured to compensate for any drift in the threshold voltage as a function of an ambient temperature of the memory cell.

13. The memory device of claim 12, wherein the temperature compensation device comprises an electrical voltage generator configured to apply an offset voltage to a substrate well of the selection transistor.

14. The memory device of claim 12, wherein the temperature compensation device comprises an electrical voltage generator configured to apply an offset voltage to a channel region of the selection transistor.

15. The memory device of claim 14, wherein the channel region is sufficiently doped to produce a desired characteristic response of the threshold voltage over a temperature range, the doping being done on the basis of an adjusted threshold voltage curve achieved by the temperature compensation device.

16. A method for writing to and/or reading from a memory cell having a selection transistor and a storage capacitor, the method comprising:
determining an ambient temperature for the memory cell; and
applying an electrical voltage to the selection transistor as a function of the determined ambient temperature such that a threshold voltage for the selection transistor is influenced contrary to an influence of the ambient temperature.

17. The method of claim 16, wherein the electrical voltage is applied to a channel region of the selection transistor.

18. The method of claim 17, wherein the channel region is sufficiently doped to produce a desired characteristic response of the threshold voltage over a temperature range, the doping being done on the basis of a temperature-adjusted threshold voltage curve achieved by the application of the electrical voltage.

19. A method for writing to and/or reading from a memory cell having a selection transistor and a storage capacitor, the method comprising:
determining an ambient temperature for the memory cell; and
applying an electrical voltage to the selection transistor as a function of the determined ambient temperature such that any ambient-temperature-induced drift in a threshold voltage for the selection transistor is compensated for

20. The method of claim 19, wherein applying the electrical voltage to compensate for any ambient-temperature-induced drift in the threshold voltage results in a substantially linear response curve of the threshold voltage.

21. The method of claim 19, wherein the electrical voltage is applied to a channel region of the selection transistor and wherein the channel region is sufficiently doped to produce a desired characteristic response of the threshold voltage over a temperature range, the doping being done on the basis of a temperature-adjusted threshold voltage curve achieved by the application of the electrical voltage.

22. The method of claim 19, wherein determining the ambient temperature for the memory cell is done by a temperature sensor and applying the electrical voltage is done by a voltage generator that receives a signal from the temperature sensor, the signal reflecting the determined ambient temperature.
